(19) United States
(12) Patent Application Publication
(10) Pub. No.: US 2006/0012014 A1
(43) Pub. Date: Jan. 19, 2006

(54) Reliability of low-k dielectric devices with energy dissipative layer

(75) Inventors: Shyng-Tsong T. Chen, Patterson, NY (US); Stefanie R. Chiras, Peekskill, NY (US); Michael Lane, Cortlandt Manor, NY (US); Qinghuang Lin, Yorktown Heights, NY (US); Robert Rosenberg, Cortlandt Manor, NY (US); Thomas M. Shaw, Peekskill, NY (US); Terry A. Spooner, New Fairfield, CT (US)

Correspondence Address: Steven Fischman, Scully,;Scott, Murphy & Presser, 400 Garden City Plaza, Garden City, NY, 11530, US

(73) Assignee: INTERNATIONAL BUSINESS MACHINES CORPORATION, ARMONK, NY (US)

(21) Appl. No.: 10/891,605

(22) Filed: Jul. 15, 2004

(51) Int. Cl. H01L 21/44

(52) U.S. Cl. 257/635

(57) ABSTRACT

The present invention provides a plastically and/or viscoelastically deformable layer that can be used in conjunction with a low-k dielectric (k of less than 4.0) to provide an electronic semiconductor structure having improved reliability. The deformable layer can be incorporated into various points within an electronic structure to dissipate energy within the structure that may cause the low-k dielectric material to crack or delaminate therefrom. Moreover, the presence of the deformable layer with the electronic structure improves the overall strength of the resultant structure.

### FIELD OF THE INVENTION

The present invention relates to electronic semiconductor devices, and more particularly to electronic semiconductor structures in which a plastically and/or viscoelastically deformable layer or partial layer thereof is present. The presence of the deformable layer or partial layer thereof in the electronic structure- improves the overall strength of the structure compared with structures that do not contain such a deformable layer.

### BACKGROUND OF THE INVENTION

The fabrication of electronic devices, particularly microelectronic semiconductor devices such as integrated circuits (ICs), involves the deposition of many different layers of metal and insulation. Typically, the insulation layers are Si-based materials such as, for example, fluorinated silicate glass (FSG), silicon dioxide, silicon oxynitride, carbon doped oxides (so-called CDOs or SiCOH), nitrided SiC, silicon nitride and the like. These insulation layers may be located either between metal lines where they serve as interlevel dielectrics, on top of metal lines or below the lines where they may serve as diffusion barriers or etch stop layers. The metal lines are typically Cu in current technology that are encased in a rigid liner material such as, for example, TaN, Ta, Ti, TiN, W or the like.

A general feature of the insulation materials is that they are brittle meaning that they behave elastically or mostly elastically (linear stress-strain curve) until failure. In other terms, there is a fixed amount of energy required to cause the insulation material in typically electronic devices to break; the energy is invariant. The same is true of the linear material as well. Cu, however, does not behave in the same way. Bulk Cu has a defined yield point at which it plastically deforms. However, it is well known that the yield point of Cu depends on the average grain size and for the dimensions commonly encountered in microelectronic semiconductor devices, the Cu yield stress becomes very high and may be considered for all practical purposes to behave in a brittle manner when encapsulated in the liner material. Because of this, the overall microelectronic device is subject to cracking and delamination of which the controlling aspect is the weakest film or interface created by two brittle films such as two insulators.

As microelectronic device technology proceeds, performance benefits may be made by changing the insulation materials from those with relatively high dielectric constants (on the order of 4.0 or greater) to those with lower dielectric constants (k of less than 4.0). However, it is well established that as the dielectric constant of the insulation material decreases, the strength of the insulation materials decreases at an even faster rate. Therefore, new device technology is need that will face the ever-increasing risks of cracking and delamination due to the brittle nature of the dielectric films.

A typical prior art interconnect structure in which cracking and delamination may occur is shown, for example, in FIG. 1A. Specifically, FIG. 1A shows a multilevel level interconnect structure 10 which includes interlayer dielectrics 14, 16, 18 and 20 which are typically composed of the same or different low-k dielectric material. The lowest most interlevel dielectric layer, i.e., layer 14 is typically formed upon a semiconductor substrate 12 that includes one or more electronic devices. By low-k, it is meant a dielectric, i.e., insulator, having a dielectric constant that is less than 4.0, e.g., less than the k for SiO₂. Illustrative examples of low-k dielectric materials that can be employed as the interlayer dielectrics include, for example, undoped silicon glass (USG), fluorosilicate glass (FSG), organo silicate glass (OSG), porous OSG, air or vacuum or any combination thereof. The interlayer dielectrics are typically formed by chemical vapor deposition (CVD), plasma enhanced chemical vapor deposition (PECVD), spin-on techniques and the like.

The conventional interconnect structure also includes one or more metal lines or vias, i.e., interconnects, 22 which are composed of a conductive metal such as W, Cu, Al, Ag and the like. The metal lines and vias are typically formed via lithography, etching and deposition of a conductive metal. An optional liner that prevents diffusion of conductive metal into the low-k dielectric can be formed prior to deposition of the conductive metal line or via. The interconnect structure also includes a diffusion barrier layer 24 which may be composed of SiC, NSiC, SiN, CoWP, SiOC, NSiOC or other known diffusion barrier materials. The diffusion barrier layer 24, which serves to protect the one or more metal lines and vias, is typically formed atop each of the interlevel dielectrics.

FIG. 1B shows another conventional interconnect structure in which a hardmask 26, such as an oxide, nitride, oxynitride or any combination thereof, is formed between the interconnects 22 to protect the interlevel dielectric 14.

As stated above, in each of the aforementioned interconnect structures which include low-k interlevel dielectrics, cracking and delamination typically occurs since the strength of the low-k dielectrics employed is relatively poor.

In view of the above problem with prior are electronic structures, there is a need for providing a new and improved electronic structure in which the energy associated with cracking and delamination of the low-k dielectric is substantially dissipated in the structure thereby providing an improved and highly reliability low-k device.

### SUMMARY OF THE INVENTION

The present invention solves the aforementioned problems mentioned in the prior art by incorporating a plastically and/or viscoelastically deformable layer within the electronic semiconductor structure. The plastically deformable layer employed in the present invention includes any polymeric material that can undergo plastic deformation, while the viscoelastically deformable layer employed in the present invention includes any polymeric material that can undergo viscoelastic deformation. Plastic deformation is a time-independent, non-linear behavior of a plastic polymeric material, while viscoelastic deformation is a time-dependent, non-linear behavior of a viscoelastic polymeric material.

The presence of the plastically and/or viscoelastically deformable material in an electronic semiconductor structure containing a low-k dielectric takes the load of the low-k dielectric thereby increasing the overall strength of the device. Additionally, the presence of the plastically and/or viscoelastically deformable material in an electronic structure containing a low-k dielectric prevents the low-k dielectric from peeling away from the electronic structure as well as providing a moisture barrier for the electronic device. Furthermore, the deformable layer employed in the present invention is thermally stable up to a temperature of about 400° C. thereby it is capable of withstanding the thermal processing of typically back-end-of-the-line (BEOL) processing. Hence, by incorporating a plastically and/or viscoelastically deformable material within a structure containing a low-k dielectric, an improved, highly reliable low-k semiconductor structure is provided since the deformable layer serves as an energy dissipation layer in the structure.

In broad terms, the present invention provides an electronic structure that includes at least one of a plastically or viscoelastically deformable layer.

In a preferred embodiment of the present invention, the electronic structure is an interconnect structure that includes a low-k dielectric material (k is less than 4.0) in proximity to the deformable layer.

The present invention also provides a method of forming the deformable layer within an electronic structure, particularly within an interconnect structure.

### BRIEF DESCRIPTION OF THE DRAWINGS

FIGS. 1A-1B are pictorial representations (through cross sectional views) illustrating a prior art interconnect-structure.

FIG. 2 is a pictorial representation (through a cross sectional view) illustrating a multilevel interconnect structure of the present invention in which a deformable layer is incorporated therein.

FIG. 3 is a pictorial representation (through a cross sectional view) illustrating another multilevel interconnect structure of the present invention in which a deformable layer is incorporated therein.

FIG. 4 is a pictorial representation (through a cross sectional view) illustrating a single level interconnect structure of the present invention in which a deformable layer is incorporated therein.

FIG. 5 is a pictorial representation (through a cross sectional view) illustrating an interconnect structure in which a deformable layer of the present invention is inserted at the bottom of the trench or interconnect line.

FIG. 6 is a pictorial representation (through a cross sectional view) illustrating an interconnect structure in which a deformable layer of the present invention is inserted below a diffusion layer or below a hardmask.

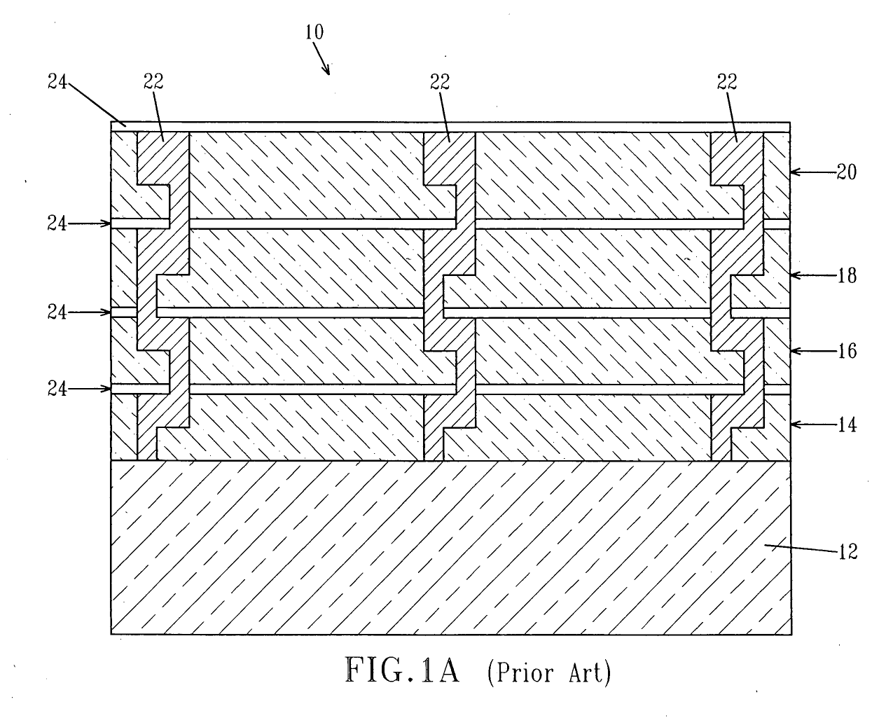

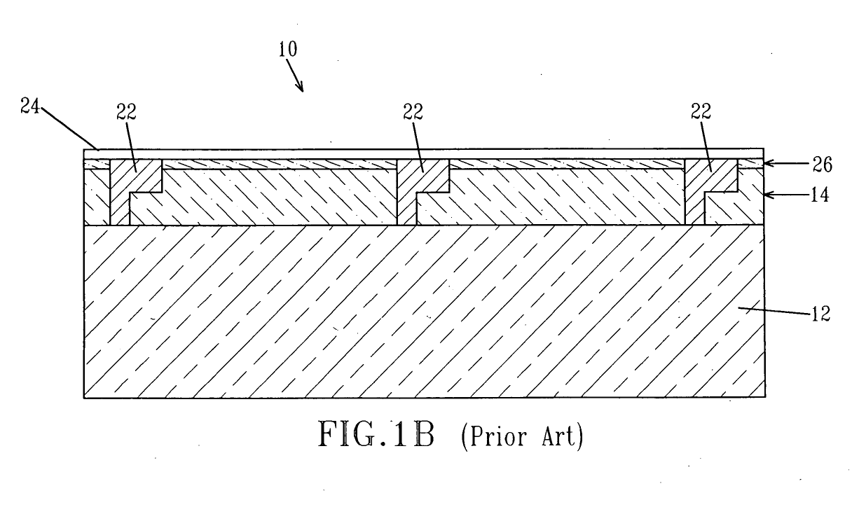

### DETAILED DESCRIPTION OF THE INVENTION

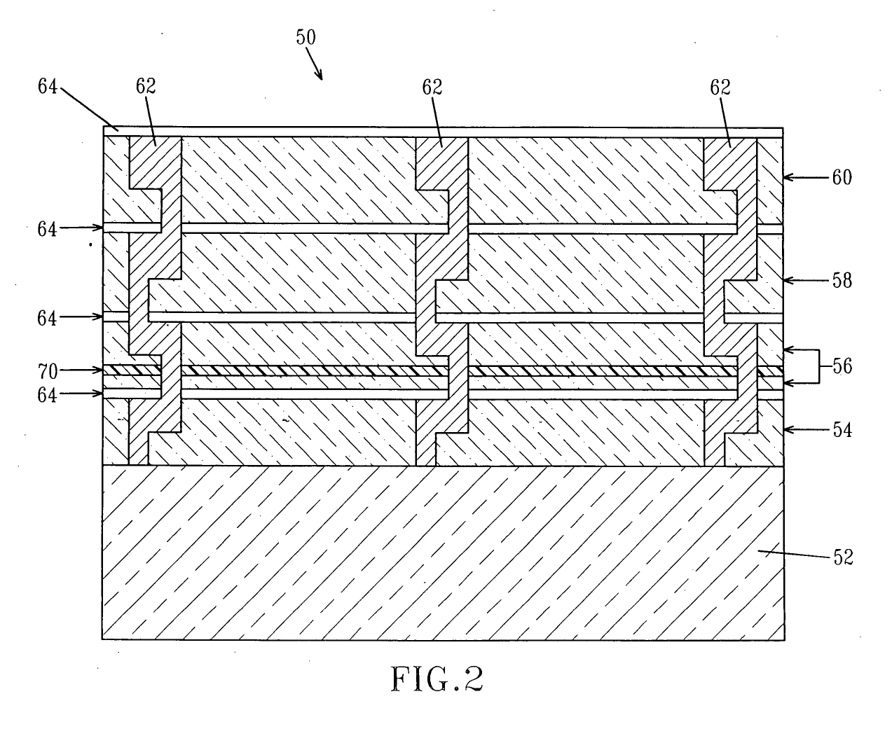

The present invention, which provides a semiconductor structure including a plastically and/or viscoelastically deformable layer, as an energy dissipation layer, will now be described in more detail by referring to the following discussion and drawing FIGS. 2-6. It should be noted that although the drawings of the present invention illustrate a specific multilevel interconnect structure, the present invention is not limited to interconnect structures that contain only the illustrated number of interlevel dielectric layers. Moreover, despite describing the use of the deformable layer in an interconnect structure, the present invention is not limited to such a structure. Instead, the deformable layer of the present invention can be incorporated within any semiconductor structure in which a low-k dielectric is employed. In FIGS. 2-6, like reference numerals are used in describing like and/or corresponding elements of the interconnect structure.

Reference is first made to the interconnect structure 50 shown in FIG. 2. The interconnect structure 50 of the present invention includes semiconductor substrate 52 having at least one interlevel low-k dielectric material formed thereon. In the drawing, interlevel dielectrics 54, 56, 58 and 60 are shown. The structure also includes one or more metal lines or vias, i.e., interconnect regions, 62 which run throughout the various interlevel dielectrics and contact a surface portion of semiconductor substrate 52. The structure also includes one or more diffusion barrier layers 64 which are located atop each interlevel low-k dielectric material. In addition to the above elements, the inventive structure also includes a deformable layer 70 which is capable of undergoing either plastic or viscoelastic deformation. The deformable layer 70 may also include a combination of materials that can undergo both plastic deformation as well as viscoelastic deformation.

The interconnect structure 50 shown in FIG. 2 minus the deformable layer 70 includes conventional components that are well known to those skilled in the art. Moreover, the interconnect structure minus the deformable layer 70 is formed using conventional BEOL processing steps that are also well known to those skilled in the art. For example, a single or dual damascene process can be used in forming the interconnect structure. Alternatively, simple deposition, lithography and etching steps can be used in forming the interconnect structure.

Semiconductor substrate 52 of interconnect structure 50 includes any semiconducting material including, but not limited to: Si, SiGe, SiC, SiGeC, Ga, GaAs, InP, InAs and other like semiconductors. The substrate 52 can also be comprised of a layered semiconductor material such as a silicon-on-inuslator (SOI), sapphire-on-insulator, SiGe-on-insulator (SGOI) and the like. The substrate 52 may include various circuits and/or devices (not shown). The substrate 52 may also include an adhesion promoter (not shown) thereon which aides in adhering the substrate with the overlaying interlevel dielectric.

The interlevel dielectrics employed in the present invention as layers 54, 56, 58 and 60 include the same or different low-k dielectric material. The low-k dielectric materials, which have a dielectric constant less than 4.0, that can be employed in the present invention include any organic, inorganic or hybrid inorganic/organic insulating material. Examples of low-k dielectrics that can be employed in the present invention include, but are not limited to: undoped silicate glass (USG), fluorosilicate glass (FSG), organo silicate glass (OSG) and the like. The low-k dielectric material can be porous or non-porous. Air and vacuum are also contemplated herein as a possible choice for the low-k dielectric material.

The low-k dielectric material is formed in the present invention utilizing a deposition process such as, for example, CVD, PECVD, spin-on techniques, evaporation, chemical solution deposition or other like deposition processes. Although not shown, a conventional adhesion promoter, such as an alkoxysilane, may be applied to the upper surface of each low-dielectric layer.

Another component of the inventive interconnect structure is one or more metal lines or vias (hereinafter interconnect regions) 62 which comprise the same or different conductive metal. The term “conductive metal” is used herein to denote a metal selected from the group consisting of aluminum (Al), copper (Cu), tungsten (W), silver (Ag) and other like metals that are typically employed in interconnect technology. Alloys of these conductive metals, such as an alloy of Al—Cu, are also contemplated herein. A preferred metal used in today's interconnect structure is Cu. The metal is formed utilizing a conventional deposition process such as CVD, PECVD, plating, sputtering, chemical solution deposition and other like processes.

In some embodiments, an optional liner (not shown) can be formed prior to deposition of the conductive metal within a trench formed in the interlevel dielectric which would prevent the diffusion of the conductive metal into the dielectric layers. Some examples of such liners include, but are not limited to: TiN, TaN, Ti, Ta, W, Wn, Cr, Nb and other like materials including combinations thereof. The optional liner material is formed utilizing a conventional deposition process such as CVD, PECVD, sputtering, plating, and chemical solution deposition.

Another component of the interconnect structure 50 shown in FIG. 2 is a diffusion barrier layer 64 that may, or may not, be formed atop each interlevel dielectric material. In the illustrative structure shown in FIG. 2, a diffusion barrier layer 64 is present atop each interlevel dielectric. The diffusion barrier layer includes any material that is resistant to diffusion of moisture or gases into the interconnect structure. Illustrative examples of suitable diffusion barrier materials include: SiC, NSiC, SiN, CoWP, SiOC, NSiOC and other like material. The diffusion barrier layer 64 is formed utilizing a conventional deposition process such as, for example, CVD, PECVD, evaporation, chemical solution deposition and the like.

The other element of the interconnect structure 50 shown in FIG. 2 is a deformable layer 70 which serves as an energy dissipative layer in the structure. More details concerning the deformable layer 70 will be made below after each structure is described. In the structure shown in FIG. 2, the deformable layer 70 is formed within one of the interlevel dielectric layers. It is noted that although such an embodiment is depicted, the deformable layer 70 may be inserted at any point or multitude of points in the interconnect structure.

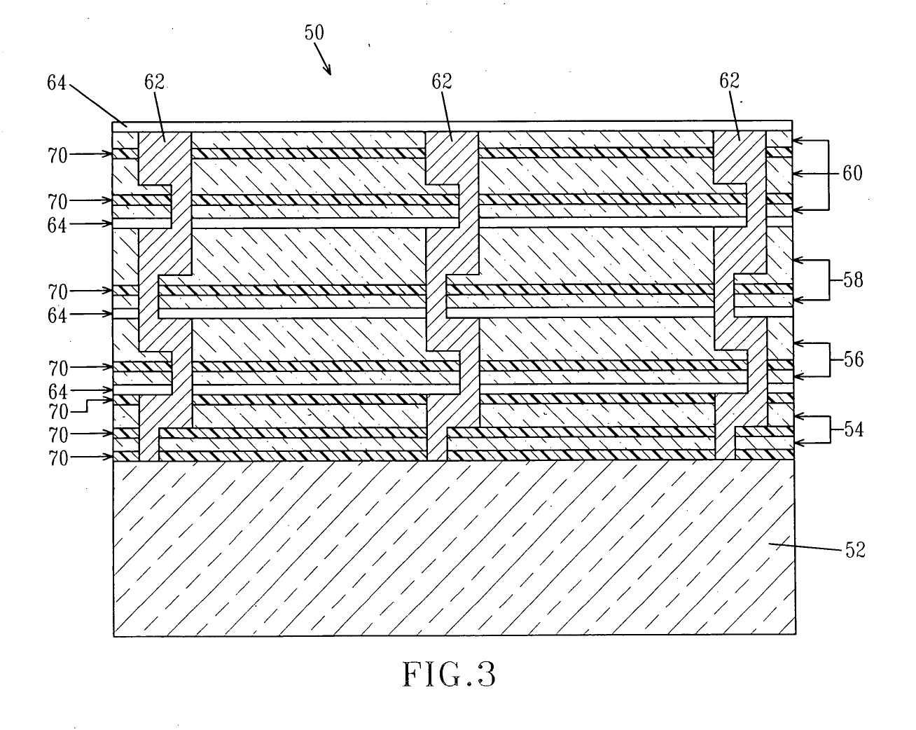

FIG. 3 shows an embodiment of the present invention in which deformable layer 70 is formed at multiple points within the interconnect structure.

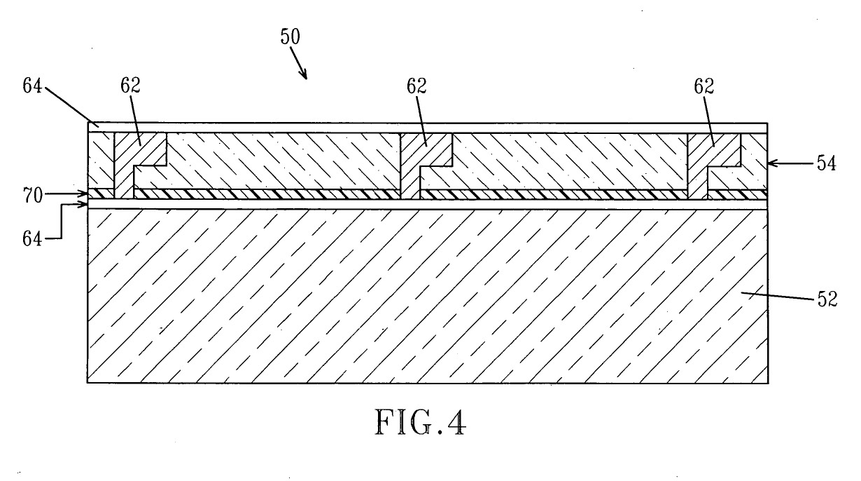

FIG. 4 shows yet another embodiment of the present invention in which the deformable layer 70 is formed on top of one of the diffusion barrier layers 64 on a single level. Although the insertion of the deformable layer is shown atop a diffusion barrier layer in a single level, the present invention contemplates a similar insertion on top of each diffusion barrier layer in multiple levels.

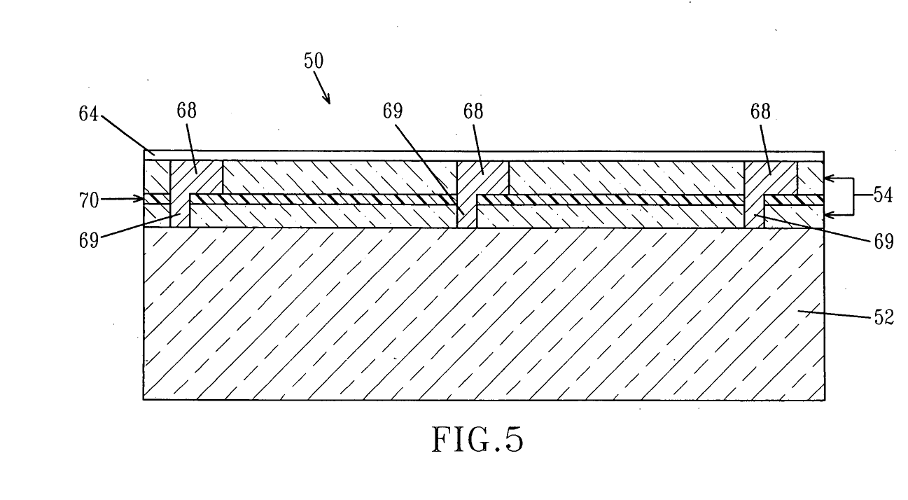

FIG. 5 shows still yet another embodiment of the present invention in which deformable layer 70 is formed at the bottom of each metal line at a single level. In this drawing, the metal line is labeled as 68 and the via is labeled as 69. The metal line 68 and the via 69 are components of the interconnect region 62 mentioned above. Although the insertion of the deformable layer is shown beneath a metal line in a single level, the present invention contemplates a similar insertion beneath each metal line in multiple levels.

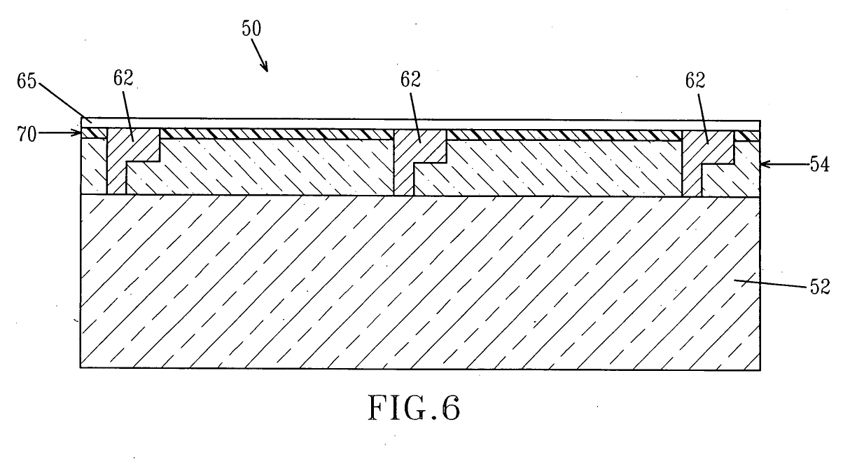

FIG. 6 shows an even further embodiment of the present invention in which the deformable layer 70 is inserted below either a diffusion barrier layer or a hardmask layer. In FIG. 6, reference numeral 65 is used to include both types of layers. The diffusion barrier includes one of the above-mentioned materials, while the hardmask is comprised of an oxide, nitride, oxynitride or a combination thereof. The hardmask is formed utilizing a deposition process such as CVD, PECVD, evaporation, chemical solution deposition and the like. Alternatively the hardmask can be formed by a thermal process.

It is again emphasized that the elements and methodology used in forming the interconnect structures shown in FIGS. 2-6 minus the deformable layer 70 are conventional and well known to those skilled in the art.

The deformable layer 70 employed in the present invention is any polymeric material that is capable of undergoing plastic or viscoelastic deformation. Plastic deformation is a time-independent, non-liner behavior of a plastic material. See, T. L. Anderson, “Fracture Mechanics” 1995, CRC Press. A plastic is a material that is capable of being deformed continuously and permanently in any direction without rupture. Viscoelastic deformation is a time dependent, non-linear behavior of a plastic material. The deformable material may be a single polymer or an admixture of polymers. In one embodiment, the deformable material comprises both an organic element and at least one inorganic functional group that improves adhesion to adjacent layers.

The polymers used in forming the deformable layer 70 are typically a thermoset. More preferably, the polymers are typically a crosslinked polyarylene ether. The polymer may also include other thermosetting materials such as inorganic thermosets and other organic thermosets, including crosslinked polyarylene ether, polybenzoxazole, polysiloxane, poly(silsesquoixane), epoxy resin, polymides, etc. The term “thermoset polymer” denotes a polymer that is capable of being changed into a substantially infusible or insoluble product when cured by heat or other means. In addition to thermosetting polymers, a thermoplastic polymer such as polyether, polysulfone, polysulfide, polycarbonate, polynorbonene, and etc, can be used alone or in conjunction with a thermosetting polymer. The term “thermoplastic polymer” denotes a polymer that is capable of being repeatedly softened by heating and hardening by cooling through a characteristic temperature range, and that in the softened state it can be shaped by flow. Thermoplastic applies generally to those materials whose change upon heating is substantially physical, rather the chemical.

The polymer material that undergoes either plastic deformation or viscoelastic deformation typically includes a Si-containing compound. The Si-containing compound can be monomeric or polymeric and can be selected from siloxanes, silsesquixoanes, silanes, carbosilanes, carbosilazanes and other like Si-containing compounds. Preferably, the deformable layer 70 is a polyarylene ether that contains Si functional groups.

The deformable layer 70 is a thin layer whose thickness is typically less than the thickness of a conventional interlayer dielectric. Typically, the deformable layer 70 has a thickness from about 50 to about 300 Å, with a thickness from about 50 to about 150 Å being more typical. For comparison, a typical interlevel dielectric has a thickness that ranges 500 to about 10,000 Å.

The deformable layer 70 can be formed by a deposition process including for example, atomic layer deposition (ALD), plasma enhanced chemical vapor deposition (PECVD), chemical vapor deposition (CVD), spin-on coating, dip coating, spray coating, evaporation or other like process. After deposition, a rinse and drying step may be performed. The rinsing and drying steps ensure that all residue solvent present in the deformable layer after deposition is removed.

The rinsing step comprises rinsing the deposited deformable layer with distilled water or another inert solvent. Rinsing may be repeated any number of times, as desired. The drying step is typically performed at a temperature from about 100° to about 425° C. in an inert ambient. Drying may also be carried out at ambient temperature as well or under vacuum. More typically, the drying step is performed at a temperature from about 280° to about 400° C. The drying step may be performed for a variable time period that can range from about 5 to about 90 minutes. Longer or shorter drying times are also contemplated.

Following deposition and/or the rinsing and drying step, the deformable layer 70 is typically cured. Curing may occur in a single step during the curing of the interlevel dielectric layers, or it may be performed immediately after deposition of the deformable layer 70. The curing step may include a hot plate bake step or furnace heating. Although the conditions for curing may vary depending of the polymeric material employed, hot plate baking is carried at a temperature from about 250° to about 500° C. for a time period from about 30 to about 500 seconds, while the furnace baking step is carried out at a temperature from about 200° to about 500° C. for a time period from about 15 minutes to about 3 hours. Again longer or shorter times are contemplated herein.

As stated above, the inventive deformable layer 70 may be incorporated into various places within the interconnect structure. Also, the method of forming the same can be easily incorporated into existing BEOL processing.

The incorporation of the deformable layer 70 into an interconnect structure containing a low-k dielectric layer has the following advantages over the prior art interconnect structures that do not contain such a layer therein:
1. Strengthen adhesion between dielectric layers
2. Enhance mechanical robustness of the structure
3. Improve mechanical reliability
4. Reduce dicing defects
5. Stop delaminations and cracks

The following examples are provided to illustrate some of the aforementioned advantages of incorporating a deformable layer into an interconnect structure as compared to interconnect structures in which such a deformable layer is not present.

### COMPARATIVE EXAMPLE 1

### Deformation Layer on Top of a Dielectric Cap

A porous pin-on glass (SOG) low-k material (JSR LKD 5109. k=2.2) was deposited on top of a Cu diffusion barrier layer comprising SiCN by spin coating and then the deposited material was baked at 80° C. for 90 sec and 200° C. for 90 sec. The film stack was cured at 425° C. for 1 hour under nitrogen. The thickness of the porous SOG low-k layer was 280 nm after curing. Fracture energy of the film stack was 0.8 J/m² as determined by a 4 point bending test. The film stack failed at the interface between the low-k material and the Cu diffusion barrier layer.

### COMPARABLE EXAMPLE 2

### Deformable Layer on Top of an Interlevel Dielectric (ILD)

A porous SOG low-k material (JSR LKD 5109, k=2.2) was deposited on top of a Cu diffusion barrier layer comprising SiCN that was coated with an adhesion promoter layer by spin coating and baked at 80° C. for 90 sec and 200° C. for 90 sec. The film stack was cured at 425° C. for 1 hour under nitrogen. A 70 nm CVD hardmask comprising a SiCOH layer was deposited on top of the porous SOG low-k layer. Fracture energy of the film stack was 2.6 J/m² as determined by a 4 point bending test.

### EXAMPLE 1

A 8 nm polyarylene ether containing Si functional groups (FF-02, JSR Microelectronics) was deposited on top of a Cu diffusion barrier layer of SiCN by spin coating and baked at 310° C. for 2 min. A porous SOG low-k material (JSR LKD 5109, k=2.2) was subsequently deposited by spin coating and baked at 80° C. for 90 sec and 200° C. for 90 sec. The film stack was cured at 425° C. for 1 hour under nitrogen. Fracture energy of the film stack was 3.2 J/m² as determined by a 4 point bending test. The film stack was found to fail cohesively in the low-k material barrier layer.

### EXAMPLES 2-5

A polyarylene ether containing Si functional groups (FF-02, JSR Microelectronics) (thickness=16 nm (Example 2), 24 nm (Example 3), 32 nm (Example 4) and 40 nm (Example 5)) was deposited on top of Cu diffusion barrier layer of SiCN by spin coating and baked at 310° C. for 2 min. A porous SOG low-k material (JSR LKD 5109, k=2.2) was subsequently deposited by spin coating and baked at 80° C. for 90 sec and 200° C. for 90 sec. The film stack was cured at 425° C. for 1 hour under nitrogen. Fracture energy of the film stack was between 3.3−˜9 J/m² based on polymer layer thickness, respectively, as determined by a 4 point bending test. The film stack was found to fail cohesively in the low-k material barrier layer.

### EXAMPLE 6

A porous SOG low-K material (JSR LKD 5109) was deposited on top of a Cu diffusion barrier layer of SiCN coated with an adhesion promoter layer by spin coating and baked at 80° C. for 90 sec and 200° C. for 90 sec. A polyarylene ether containing Si functional groups (FF-02, JSR Microelectronics) was deposited on top of the porous SOG low-k layer by spin coating and baked at 310° C. for 2 min. The film stack was cured at 425° C. for 1 hour under nitrogen. A 70 nm CVD hardmask of SiCOH was deposited on top of the porous SOG low-k layer. Fracture energy of the film stack was 3.2 J/m² as determined by a 4 point bending test.

While the present invention has been particularly shown and described with respect to preferred embodiments thereof, it will be understood by those skilled in the art that the foregoing and other changes in forms and details may be made without departing from the scope and spirit of the present invention. It is therefore intended that the present invention not be limited to the exact forms and details described and illustrated, but fall within the scope of the appended claims.

What we claim is:

1. An electronic structure comprising at least one of a plastically or viscoelastically deformable layer.

2. The electronic structure of claim 1 further comprising at least one low-k dielectric layer that is in proximity to said deformable layer.

3. The electronic structure of claim 2 wherein said-at least one low-k dielectric layer is part of an interconnect structure.

4. The electronic structure of claim 2 wherein said at least one low-k dielectric layer comprises undoped silicon glass, a fluorosilicate glass, or an organo silicate glass.

5. The electronic structure of claim 4 wherein said at least one low-k dielectric layer is porous.

6. The electronic structure of claim 3 wherein said interconnect structure further comprises one or more metal lines and vias.

7. The electronic structure of claim 6 wherein said one or more metal lines and vias comprises at least one conductive metal.

8. The electronic structure of claim 6 wherein said at least one conductive metal comprises Cu, Al, W, or Ag.

9. The electronic structure of claim 3 further comprising a diffusion barrier layer located atop the at least one low-k dielectric layer.

10. The electronic structure of claim 9 wherein said diffusion barrier layer comprises SiN, SiC, SiOC, NSiC, NSiOC, SiCOH, CoWP or Ta.

11. The electronic structure of claim 1 wherein said deformable layer is located below a diffusion barrier layer.

12. The electronic structure of claim 1 wherein said deformable layer is present within at least one low-k dielectric layer.

13. The electronic structure of claim 1 wherein said deformable layer is present below a hardmask.

14. The electronic structure of claim 1 wherein said deformable layer is present beneath a metal line present in at least one low-k dielectric layer.

15. The electronic structure of claim 1 wherein said deformable layer is a thermosetting or thermoplastic polymer.

16. The electronic structure of claim 1 wherein the deformable layer is an admixture of polymers.

17. The electronic structure of claim 16 wherein said admixture comprises at least one thermoplastic polymer and at least one thermosetting polymer.

18. The electronic structure of claim 1 wherein said deformable layer comprises a Si-containing compound.

19. The electronic structure of claim 18 wherein said Si-containing compound comprises a siloxane, a silsequioxane, a silane, a carbosilane, a carbosilazane or any combination thereof.

20. The electronic structure of claim 1 wherein said deformable layer is a polyarylene ether.

21. The electronic structure of claim 1 wherein said deformable layer has a thickness from about 50 to about 300 Å.

22. An interconnect structure comprising
at least one low-k dielectric layer located atop a semiconductor substrate having electronic devices formed therein;
at least one interconnect region comprising metal lines and vias within said at least one low-k dielectric layer; and
at least one of a plastically or viscoelastically deformable layer in proximity to said at least one low-k dielectric layer.

23. The interconnect structure of claim 22 wherein said at least one low-k dielectric layer comprises a plurality of low-k materials stack on top of each other, wherein a diffusion barrier layer is located between each low-k material.

24. The interconnect structure of claim 22 wherein said deformable layer is a thermosetting or thermoplastic polymer.

25. The interconnect structure of claim 22 wherein the deformable layer is an admixture of polymers.

26. The interconnect structure of claim 25 wherein said admixture comprises at least one thermoplastic polymer and at least one thermosetting polymer.

27. The interconnect structure of claim 22 wherein said deformable layer comprises a Si-containing compound.

28. The interconnect structure of claim 27 wherein said Si-containing compound comprises a siloxane, a silsequioxane, a silane, a carbosilane, a carbosilazane or any combination thereof.

29. The interconnect structure of claim 22 wherein said deformable layer is a polyarylene ether.

30. The interconnect structure of claim 22 wherein said deformable layer has a thickness from about 50 to about 300 Å.

31. A method of forming a reliably electronic structure, said method comprising
forming at least one of a plastically or viscoelastically deformable layer in proximity to a at least one low-k dielectric layer.

32. The method of claim 31 wherein said forming comprises a deposition step.

33. The method of claim 32 further comprising a rinsing and drying step.

34. The method of claim 33 further comprising a curing step.

35. The method of claim 32 further comprising a curing step.

36. The method of claim 31 wherein said forming step is integrated as one step of a back-end-of-the-line (BEOL) chip manufacturing process.

37. The method of claim 31 wherein said deformable layer is a thermosetting or thermoplastic polymer.

38. The method of claim 31 wherein the deformable layer is an admixture of polymers.

39. The method of claim 38 wherein said admixture comprises at least one thermoplastic polymer and at least one thermosetting polymer.

40. The method of claim 31 wherein said deformable layer comprises a Si-containing compound.

41. The method of claim 40 wherein said Si-containing compound comprises a siloxane, a silsequioxane, a silane, a carbosilane, a carbosilazane or any combination thereof.

42. The method of claim 31 wherein said deformable layer comprises a polyarylene ether.
